(19) United States
(12) Patent Application Publication
(10) Pub. No.: US 2013/0083505 A1
(43) Pub. Date: Apr. 4, 2013

(54) WIRING BOARD, CONNECTOR AND ELECTRONIC APPARATUS

(71) Applicant: Noriyuki Kobayashi, Kanagawa (JP)

(72) Inventor: Noriyuki Kobayashi, Kanagawa (JP)

(73) Assignee: Sony Corporation, Tokyo (JP)

(21) Appl. No.: 13/609,690

(22) Filed: Sep. 11, 2012

(30) Foreign Application Priority Data
Oct. 4, 2011 (JP) 2011-220178

(51) Int. Cl. H05K 1/14; H01R 24/00; H05K 1/00

(52) U.S. Cl. 361/785; 174/250; 439/629

(57) ABSTRACT

Disclosed herein is a wiring board including: a differential-line pair including two lines for transmitting differential signals; and two connection pads each electrically connected to one of the two lines pertaining to one of the differential-line pairs, wherein a plurality of the differential-line pairs are laid out side by side; a plurality of the connection pads are provided to form a plurality of columns; and on each of the columns of the connection pads, any two the connection pads electrically connected to the lines pertaining to the same differential-line pair are provided at locations adjacent to each other on the same one of the columns.

### BACKGROUND

The present technology disclosed in this specification relates to a wiring board including two lines for transmitting differential signals, connectors connected to the wiring board and an electronic apparatus which includes the wiring board and the connectors.

In an electronic apparatus on which electronic circuits are mounted at a high density, in many cases, a differential-signal transmission method is adopted to serve as a method for transmitting signals between the electronic circuits. The differential-signal transmission method is noise-proof even if the transmitted signal has a small amplitude. In particular, in order to implement a differential-signal transmission method for transmitting differential signals between ICs each having circuits integrated therein, there is used a flexible wiring board proper for the differential-signal transmission method as disclosed in Japanese Patent Laid-open No. 2010-74095 (Patent Document 1).

Patent Document 1 discloses a flexible wiring board connecting two printed wiring boards through connectors. On each of the printed wiring boards, circuit components such as ICs have been integrated.

On the flexible wiring board, a plurality of pairs are created. The pairs each have two lines provided for respectively the P and N channels of differential electrical signals transmitted along the lines. In the following description, the pair having the two lines is referred to as a differential-line pair. On each of the two longitudinal-direction sides of each of the differential-line pairs, there is provided an edge of the flexible wiring board. On each of the edges, a connector is provided. The connector includes terminals or electrodes. The connectors of the differential-line pairs include outer-side column electrodes and inner-side column electrodes. An outer-side column electrode is an electrode provided on the edge side (or the outer side) of the flexible wiring board. On the other hand, an inner-side column electrode is an electrode provided on the wiring-area side (or the inner side) of the differential-line pair.

In the flexible wiring board disclosed in Patent Document 1, on a specific one of the connectors, the P-channel signal line of the differential-line pair is connected to the outer-side column electrode whereas the N-channel signal line of the differential-line pair is connected to the inner-side column electrode. On the other one of the connectors, on the other hand, the N-channel signal line of the differential-line pair is connected to the outer-side column electrode whereas the P-channel signal line of the differential-line pair is connected to the inner-side column electrode. That is to say, the connections of the P-channel signal line and the N-channel signal line to the outer-side column electrode and the inner-side column electrode in the specific connector are opposite to the connections of the P-channel signal line and the N-channel signal line to the outer-side column electrode and the inner-side column electrode in the other connector.

Thus, the length of the P-channel signal line is equal to the length of the N-channel signal line, providing a balanced state. As a result, it is possible to provide a configuration in which a wiring skew in the P and N channels of differential signals can be eliminated to a certain degree. In the following description, the wiring skew is also referred to as a differential skew.

Patent Document 1 also discloses a first connector which is referred to as a connector acceptor-section mounted on the printed wiring board.

The edge employed in the flexible wiring board and provided with the connector is plugged into the connector acceptor-section mounted on the printed wiring board in the line direction of the differential-line pair. With the edge of the flexible wiring board plugged into the connector acceptor-section, long and short electrodes of the connector acceptor-section hold the edge of the flexible wiring board elastically and one of the long and short electrodes serves as a connector terminal, rubbing against an connection pad of the edge and sliding over the pad so that the connector terminal and the connection pad are electrically connected to each other.

### SUMMARY

In the electrode layout of the flexible wiring board disclosed in Patent Document 1, electrodes are put in two columns, that is, an outer-side column and an inner-side column. A specific one of the two ends of a specific one of two lines pertaining to a differential-line pair is connected to an outer-side column electrode on a side far away from a wiring area whereas a specific one of the two ends of the other one of the two lines pertaining to the differential-line pair is connected to an inner-side column electrode on a side close to the wiring area. On the other hand, the other one of the two ends of the specific one of the two lines pertaining to the differential-line pair is connected to an inner-side column electrode whereas the other one of the two ends of the other one of the two lines pertaining to the differential-line pair is connected to an outer-side column electrode. That is to say, the connections of the two specific ones of the four ends of the two lines pertaining to the differential-line pair to the inner-side column electrode and the outer-side column electrode are opposite to the connections of the two other ones of the four ends of the two lines pertaining to the differential-line pair to the inner-side column electrode and the outer-side column electrode. Thus, it is possible to equalize the line lengths which determine the electrical lengths of differential signals. For this reason, it is absolutely necessary to apply the same electrode location structure and the same electrode allocation (connection) structure to both end sides of the differential-line pair. Accordingly, in the process of connecting the lines of the differential-line pair directly to a semiconductor chip or in another process, it is impossible to provide balance by making use of the electrical lengths of the differential signals. In this case, a differential-skew improvement effect cannot be obtained.

In addition, since the electrodes connected to the ends of the two lines which are the P-channel line and the N-channel line are an inner-side column electrode and an outer-side column electrode, the physical structure of a signal transmission conductor including the electrodes is not truly symmetrical. Thus, during a higher-speed transmission of a signal, the balance crumbles with ease due to the two differential signals (or the two single-end signals) or a timing shift occurs between the two signals. Seen in this light, the differential-skew improvement effect described in Patent Document 1 is limited in the case of a signal transmitted at a high speed.

An embodiment of the present technology disclosed in this specification can be applied to a wide range of applications due to the fact that the embodiment is applicable to an IC mounting board or the like. The embodiment implements a wiring board capable of sufficiently improving a differential skew for differential signals transmitted at a high speed.

Another embodiment of the present technology disclosed in this specification implements a connector which is proper for the structure of the wiring board and can thus be used by combining the connector with the wiring board.

A further embodiment of the present technology disclosed in this specification implements an electronic apparatus employing the wiring board.

A wiring board according to the embodiments of the present technology disclosed in this specification includes:

a plurality of differential-line pairs each including two lines for transmitting differential signals; and

a plurality of connection pad pairs each including two connection pads each electrically connected to one of the two lines pertaining to one of the differential-line pairs. In the wiring board, the differential-line pairs are laid out side by side to form a plurality of rows; the connection pads are provided to form a plurality of columns; and on each of the columns of the connection pads, any two connection pads electrically connected to the lines pertaining to the same differential-line pair are provided at locations adjacent to each other on the same column.

An electronic apparatus according to the embodiments of the present technology disclosed in this specification includes a first wiring board, a second wiring board and a connector for connecting the first wiring board to the second wiring board. In the electronic apparatus, an electronic circuit is mounted on at least one of the first wiring board and the second wiring board. The first wiring board has a configuration identical with that of the wiring board according to the embodiments of the present technology disclosed in this specification.

In the wiring board according to the embodiments of the present technology disclosed in this specification and the first wiring board employed in the electronic apparatus according to the embodiments of the present technology disclosed in this specification, the connection pads are provided to form typically two columns referred to hereafter as an inner-side column and an outer-side column respectively and, in each of the columns of the connection pads, any two connection pads electrically connected to the lines pertaining to the same differential-line pair are provided at locations adjacent to each other on the same column. Thus, adjacent connection pads provided on each of the columns can be laid out in a direction perpendicular to the line direction of the differential-line pairs. At that time, connection points between lines and connection pads can be aligned uniformly in the line direction. In this case, it is possible to achieve a configuration, in which the effective line lengths of the differential-line pairs can be made uniform so as to improve a differential skew, on only one of the sides separated away from each other in the line direction. In addition, entire signal transmission conductors each including a line and a connection pad can be made symmetrical.

A connector according to the embodiments of the present technology disclosed in this specification includes:

a socket into which a portion of a board provided with a plurality of connection-pad pairs each having two connection pads electrically connected to respectively two lines for transmitting differential signals is inserted; and

a plurality of terminal bodies which are provided inside the socket and can rub against the connection pads to slide over the connection pads on a 1-to-1 basis when the portion of the board is inserted into the socket. In the connector, the terminal bodies are laid out to form two columns composing a terminal-body matrix corresponding to a connection-pad matrix composed of the connection pads; and every two of the terminal bodies serve as connection portions for transmitting the differential signals and are provided at locations adjacent to each other on the same column.

As described above, the terminal bodies are provided inside the socket and can rub against the connection pads to slide over the connection pads on a 1-to-1 basis when a portion of the board is inserted into the socket.

The edge of the wiring board is provided with a plurality of connection-pad pairs each having two connection pads electrically connected to respectively two lines for transmitting differential signals. The edge of the wiring board is an edge to be inserted into a connector acceptor-section inside the socket. When the edge of the board is inserted into the connector acceptor-section inside the socket, the terminal bodies which are provided in the connector acceptor-section of the socket rub against the connection pads provided on the edge and slide over the connection pads on a 1-to-1 basis. For this reason, the connection pads are laid out to form two connection-pad columns and the terminal bodies are also laid out to form two terminal-body columns coinciding with the two connection-pad columns respectively. In addition, any two connection pads for transmitting the differential signals are brought into contact with respectively the two corresponding terminal bodies serving as connection portions for transmitting the same differential signals.

With such a contact configuration, the entire signal transmission conductor can have an almost symmetrical physical structure provided that contact-position shifts and the like can be kept within tolerable ranges. In this case, the signal transmission conductor includes the line, the connection pad and the terminal body which are used for transmitting differential signals.

The lengths of two lines pertaining to a differential-line pair determine the electrical lengths of differential signals transmitted along the two lines and are balanced. In addition, a structure including connection pads (and connector terminal bodies) is symmetrical. Thus, a differential skew is further improved. On top of that, since it is possible to implement a structure improving the differential skew on only one line-direction side of the differential-line pair, the application range of the present technology disclosed in this specification is wide.

### BRIEF DESCRIPTION OF THE DRAWINGS

FIGS. 1A to 1C are a diagram showing a planar pattern of conductors provided on a wiring board according to a first embodiment, a diagram showing a cross section of the wiring board along a line stretched in a direction and a diagram showing a cross section of the wiring board along a line stretched in another direction, respectively;

FIG. 2 is a diagram showing the configuration of main components employed in an electronic apparatus according to the first embodiment;

FIGS. 3A and 3B are a top-view diagram showing the bottom plane of the socket of a connector according to the first embodiment and a diagram showing a cross section of the connector, respectively;

FIGS. 4A and 4B are a top-view diagram (or a perspective diagram) showing conductors in a state in which the wiring board has been plugged into the connector in the first embodiment and a diagram showing the cross section of the wiring board plugged into the connector, respectively;

FIGS. 5A and 5B are a diagram showing a planar pattern of conductors provided on a wiring board according to a second embodiment and a diagram showing a cross section of the wiring board, respectively;

FIGS. 6A and 6B are a plurality of diagrams showing A-surface and B-surface lines of the wiring board shown in FIGS. 5A and 5B;

FIG. 7 is a diagram showing the configuration of main components employed in an electronic apparatus according to a third embodiment; and

FIG. 8 is a diagram showing the configuration of main components employed in an electronic apparatus according to a fourth embodiment.

### DETAILED DESCRIPTION OF THE PREFERRED EMBODIMENTS

Embodiments of the present technology disclosed in this specification are explained below by referring to accompanying diagrams. The embodiments implement mainly a flexible wiring board, a connector and an electronic apparatus which includes the flexible wiring board as well as the connector.

The explanation of the embodiments is divided into topics arranged in the following order:

### 1: First Embodiment

A first embodiment implements a flexible wiring board of a one-side (one-layer) type. The two line-direction edges of the flexible wiring board are each connected to another wiring board through a connector.

### 2: Second Embodiment

A second embodiment implements a flexible wiring board of a both-side (both-layer) type.

### 3: Third Embodiment

A third embodiment implements an electronic apparatus in which an electronic circuit (or an IC) is directly connected to the ends on one side of differential-line pairs constructed on a flexible wiring board.

### 4: Fourth Embodiment

A fourth embodiment implements an electronic apparatus in which an electronic circuit (or an IC) is internally connected to the ends on one side of differential-line pairs constructed on a relatively rigid wiring board.

### 5: Typical Modified Versions

### 1: First Embodiment

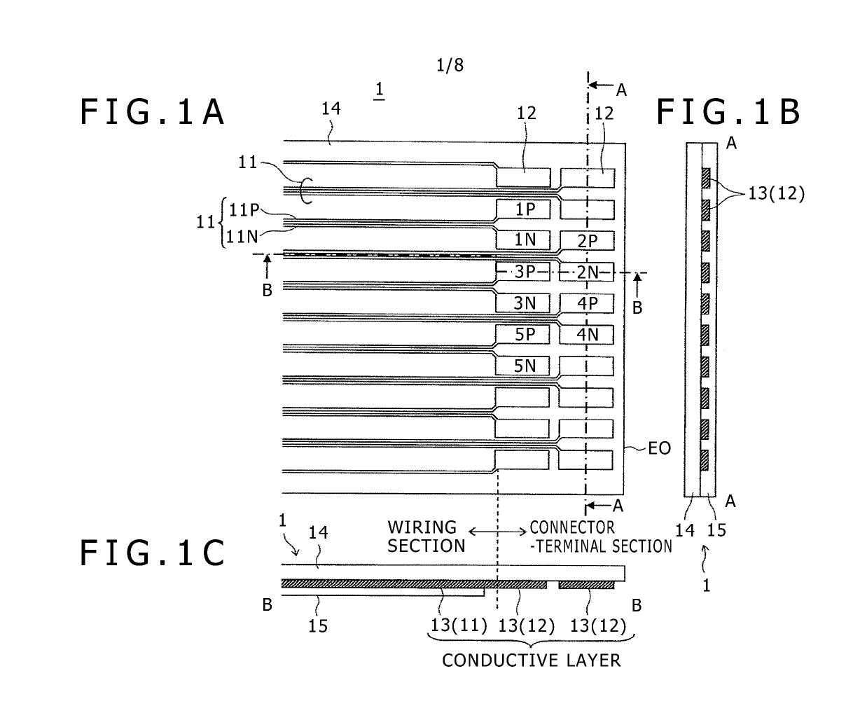

FIGS. 1A to 1C are a plurality of diagrams showing a typical configuration of a flexible wiring board 1 according to a first embodiment of the present technology disclosed in this specification. To be more specific, FIG. 1A is a diagram showing a planar pattern of conductors at an edge provided with connector terminals of the flexible wiring board 1. In this case, the conductor includes a line and a connection pad connected to the line. On the other hand, FIG. 1B is a diagram roughly showing a cross section along an A-A line shown in FIG. 1A whereas FIG. 1C is a diagram roughly showing a cross section along a B-B line shown in FIG. 1A.

In the flexible wiring board 1 shown in FIGS. 1A to 1C, a plurality of differential-line pairs 11 are created on a wiring section whereas a connector terminal group including a plurality of connection pads 12 is provided at the terminal section of a base wiring board. In the following description, the terminal section is also referred to as a connector terminal section. The pattern of the differential-line pairs 11 and the connection pads 12 will be described later in detail.

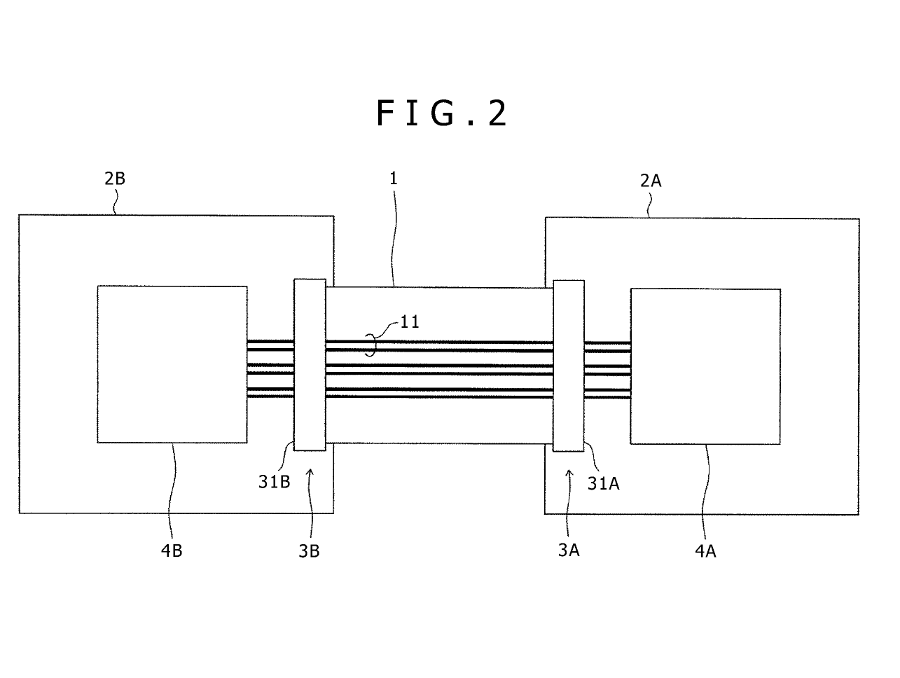

The flexible wiring board 1 shown in FIGS. 1A to 1C is a typical example of a wiring board according to the embodiments of the present technology disclosed in this specification. For example, the flexible wiring board 1 is used in a configuration shown in FIG. 2 as the configuration of an electronic apparatus according to the embodiments of the present technology disclosed in this specification. In this configuration, the flexible wiring board 1 is a typical example of a first wiring board employed in the electronic apparatus according to the embodiments of the present technology disclosed in this specification.

First of all, the configuration of the flexible wiring board 1 is explained by referring to FIG. 2.

As shown in FIG. 2, the flexible wiring board 1 serving as the first wiring board in the configuration is connected to two other wiring boards serving as second wiring boards 2A and 2B respectively. Thus, the connector-terminal group including connection pads 12 as shown in FIGS. 1A to 1C is created on each of the edges of the flexible wiring board 1.

That is to say, on a specific one of the edges of the flexible wiring board 1, connection pads 12 are created. This specific one of the edges of the flexible wiring board 1 is inserted into the socket 31A of a connector 3A provided on the second wiring board 2A. By the same token, on the other one of the edges of the flexible wiring board 1, connection pads 12 are also created as well. This other one of the edges of the flexible wiring board 1 is inserted into the socket 31B of a connector 3B provided on the second wiring board 2B.

On the second wiring board 2A, a semiconductor IC (Integrated Circuit) 4A is created. The semiconductor integrated circuit 4A can be mounted on the second wiring board 2A typically by adoption of a bear-chip mounting technique. Normally, however, the IC chip is mounted on a board in a state in which the IC chip is accommodated in a package of a type proper for the transmission frequency. By the same token, a semiconductor IC (Integrated Circuit) 4B is created on the second wiring board 2B in the same way as the semiconductor integrated circuit 4A mounted on the second wiring board 2A.

The configuration shown in FIG. 2 is the configuration of a typical example of an electronic apparatus according to the embodiments of the present technology disclosed in this specification. In addition, the semiconductor integrated circuits 4A and 4B shown in the same figure are each a typical example of an electronic circuit according to the embodiments of the present technology disclosed in this specification. In the present technology disclosed in this specification, the input to each of the semiconductor integrated circuits each serving as the electronic circuit and the output of each of the semiconductor integrated circuits are assumed to be differential signals. With this assumption holding true, the electronic circuit can have any arbitrary function. In the case of two electronic circuits exchanging differential signals having a high frequency, any specific one of the electronic circuits may serve as a signal transmitting IC whereas the other one of the electronic circuits may serve as a signal receiving IC.

By referring to diagrams, the following description explains details of a configuration including lines included in a wiring board and connector terminals of a connector included in the wiring board as well as details of a configuration of the connector terminals.

### Cross-Sectional Structure of a Wiring Board

As shown in FIGS. 1B and 1C, the cross-sectional structure of the flexible wiring board 1 has two insulation layers 14 and 15 and a conductive layer 13 between the two insulation layers 14 and 15. The flexible wiring board 1 having such a structure is referred to as a flexible wiring board of a one-layer (one-surface) type.

FIG. 1C is a cross-sectional diagram showing a state in which the flexible wiring board 1 is inserted into the connector socket 31A of a connector 3A shown in FIG. 2. In such a state, connector terminals are exposed to the lower-side surface of the flexible wiring board 1.

The insulation layer 14 on the upper surface side is an insulation layer serving as the base layer of the flexible wiring board 1. The insulation layer 14 is a board according to the embodiments of the present technology disclosed in this specification. The insulation layer 14 is made of typically a flexible resin film which has poor rigidity to serve as a board.

On the other hand, the insulation layer 15 on the lower surface side is an insulation layer used for the purpose of protection.

A representative example of the resin material used for making the insulation layers 14 and 15 is a polyimide film.

In general, the conductive layer 13 is a conductive film made of copper. However, the conductive film can also be made of a conductive material other than copper.

As shown in FIGS. 1A and 1C, the flexible wiring board 1 is divided into a connector-terminal section and a wiring section. The connector-terminal section is a portion of the flexible wiring board 1 and includes an area in which the connection pads 12 are laid out. The area in which the connection pads 12 are laid out is thus the connector-terminal section of the flexible wiring board 1. On the other hand, the wiring section is another portion of the flexible wiring board 1 and includes an area in which the differential-line pairs 11 are mainly laid out. As shown in FIG. 1C, two reference numerals 13(12) are used in order to deliberately indicate that two connection pads 12 on two columns respectively are created in the connector-terminal section from the conductive layer 13. Also as shown in FIG. 1C, on the other hand, only one reference numeral 13(11) is used in order to deliberately indicate that one differential-line pair 11 is created for each row in the wiring section from the conductive layer 13.

The insulation layer 15 covers all but the entire area of the wiring section. The insulation layer 15 is created so as to expose at least the connection pads 12.

### Conductive-Layer Pattern of the Wiring Board

As shown in FIG. 1A, the differential-line pairs 11 are laid out side by side to form rows in the wiring section. In the case of this embodiment, the pitch of the differential-line pairs 11 is fixed. Each of the differential-line pairs 11 includes a P-channel signal line 11P and an N-channel signal line 11N. The P-channel signal line 11P is used for transmitting the P-channel signal of the differential signals. On the other hand, the N-channel signal line 11N is used for transmitting the N-channel signal of the differential signals. The distance between the P-channel signal line 11P and the N-channel signal line 11N is also uniform for all the differential-line pairs 11.

The P-channel signal line 11P and the N-channel signal line 11N which are used for transmitting the differential signals are each shown as a straight line in FIG. 1A. It is to be noted, however, that portions of the P-channel signal line 11P and/or the N-channel signal line 11N may be typically bent in a gradual manner as long as the shapes of the P-channel signal line 11P and/or the N-channel signal line 11N do not result in undesired radiations caused by EMI (Electromagnetic Interferences). That is to say, as long as the P-channel signal line 11P and/or the N-channel signal line 11N are all but straight as a whole.

In the connector-terminal section, as a whole, the connection pads 12 are provided to form a reticular pattern on the two connection-pad columns. In the following description, the connector-terminal section is also referred to as a wiring-board edge. The connection-pad column close to the edge side E0 of the connector-terminal section is referred to as an outer-side column whereas the connection-pad column far away from the edge side E0 of the connector-terminal section is referred to as an inner-side column.

Both the P-channel signal line 11P and the N-channel signal line 11N which pertain to the same differential-line pair 11 are always connected to two connection pads 12 both on the outer-side column or the inner-side column. That is to say, both the P and N channels of every differential-line pair 11 are connected to two connection pads 12 both on the outer-side column or the inner-side column. By connecting the P and N channels to the two connection pads 12 in this way, the shape of the connection pads 12 physically extended from the ends of the P-channel signal line 11P and the N-channel signal line 11N can be created to have a symmetrical shape. In other words, it is desirable to create the two connection pads 12 connected to the same differential-line pair 11 to have a shape that is line-symmetrical with respect to an axis of symmetry at a specific one of the two ends of the P-channel signal line 11P and a corresponding specific one of the two ends of the N-channel signal line 11N. This axis of symmetry is an axis passing through the center of the distance between the P-channel signal line 11P and the N-channel signal line 11N, which pertain to the differential-line pair 11.

The following description explains more detailed relations between lines and connection pads in five pairs of signal transmission conductors each having a connection pad and a line which are connected to each other. In FIG. 1A, reference numerals 1P and 1N denote respectively P-channel and N-channel signal transmission conductors pertaining to the first pair of signal transmission conductors, reference numerals 2P and 2N denote respectively P-channel and N-channel signal transmission conductors pertaining to the second pair of signal transmission conductors, reference numerals 3P and 3N denote respectively P-channel and N-channel signal transmission conductors pertaining to the third pair of signal transmission conductors, reference numerals 4P and 4N denote respectively P-channel and N-channel signal transmission conductors pertaining to the fourth pair of signal transmission conductors whereas reference numerals 5P and 5N denote respectively P-channel and N-channel signal transmission conductors pertaining to the fifth pair of signal transmission conductors.

The following description of relations between lines and connection pads also holds true for other pairs of signal transmission conductors. As described above, a signal transmission conductor has a connection pad and a line which are connected to each other. The P-channel and N-channel signal transmission conductors 1P and 1N are adjacent signal transmission conductors pertaining to the same pair of signal transmission conductors. The P-channel and N-channel signal transmission conductors 1P and 1N which are adjacent to each other are referred to as differential-signal pair conductors. This explanation also holds true for the other P-channel and N-channel signal transmission conductors which are adjacent to each other.

In the configuration shown in FIGS. 1A to 1C, the two adjacent differential-signal pair conductors pertaining to the same pair of signal transmission conductors in the wiring section and the connector-terminal section are denoted by reference numerals 1P and 1N, 2P and 2N or 3P and 3N and so on. In accordance with the present technology disclosed in this specification, the differential-signal pair conductors 1P and 1N, 3P and 3N, 5P and 5N and so on pertain to their respective first differential-line pairs which are differential-line pairs provided for every other row whereas the differential-signal pair conductors 2P and 2N, 4P and 4N, 6P and 6N and so on pertain to their respective second differential-line pairs which are each a differential-line pair provided between first differential-line pairs.

As described above, the differential-signal pair conductors pertaining to their respective first differential-line pairs are denoted by odd reference numerals such as 1P and 1N, 3P and 3N, 5P and 5N and so on whereas the differential-signal pair conductors pertaining to their respective second differential-line pairs are denoted by even reference numerals such as 2P and 2N, 4P and 4N, 6P and 6N and so on.

In the configuration shown in FIG. 1A, the differential-signal pair conductors each denoted by an odd reference numeral such as 1P or 1N each include a connection pad 12 provided on the inner-side column whereas the differential-signal pair conductors each denoted by an even reference numeral such as 2P or 2N each include a connection pad 12 provided on the outer-side column.

It is to be noted that, as opposed to the configuration shown in FIG. 1A, the differential-signal pair conductors each denoted by an odd reference numeral may each include a connection pad 12 provided on the outer-side column whereas the differential-signal pair conductors each denoted by an even reference numeral may each include a connection pad 12 provided on the inner-side column. In this case, the relations between the first/second differential-line pairs and the odd/even reference numerals are opposite to the relations described before. That is to say, in this case, the first differential-line pairs are associated with the even reference numerals whereas the second differential-line pairs are associated with the odd reference numerals.

In the wiring section in particular, the lines for transmitting differential signals are the first P-channel signal line provided on the first row, the first N-channel signal line provided on the first row, the second P-channel signal line provided on the second row, the second N-channel signal line provided on the second row, the third P-channel signal line provided on the third row, the third N-channel signal line provided on the third row and so on. The lines for transmitting differential signals are thus lines arranged side by side by repetition of the P and N channels for every differential-line pair.

The P-channel signal line 11P and the N-channel signal line 11N which are provided on an odd-numbered row such as any one of the first row, the third row, the fifth row and so on are connected to their respective connection pads 12 both provided on the inner-side column. On the other hand, the P-channel signal line 11P and the N-channel signal line 11N which are provided on an even-numbered row such as any one of the second row, the fourth row, the sixth row and so on are connected to their respective connection pads 12 both provided on the outer-side column.

In these connection relations, in order to connect a differential-line pair (11P and 11N) to connection pads 12 provided on the outer-side column, the differential-line pair (11P and 11N) typically extends to the outer-side column through an area in which connection pads 12 of the inner-side column are provided.

For example, the differential-line pair (11P and 11N) provided on the second row is stretched to the outer-side column through a space between a connection pad 12 (1N) connected to an N-channel signal line 11N pertaining to the differential-line pair provided on the first row and a connection pad 12 (3P) connected to a P-channel signal line 11P pertaining to the differential-line pair provided on the third row.

By the same token, the differential-line pair (11P and 11N) provided on the fourth row is stretched to the outer-side column through a space between a connection pad 12 (3N) connected to an N-channel signal line 11N pertaining to the differential-line pair provided on the third row and a connection pad 12 (5P) connected to a P-channel signal line 11P pertaining to the differential-line pair provided on the fifth row.

The P-channel signal line 11P pertaining to the differential-line pair provided on the second row is stretched to the outer-side column through a space between two connection pads 12 (1N and 3P) provided on the inner-side column and is connected to a connection pad 12 (2P) provided on the outer-side column in a state of being extended horizontally in the row direction side by side with the connection pad 12 (1N) close to the P-channel signal line 11P.

By the same token, the N-channel signal line 11N pertaining to the differential-line pair provided on the second row is also stretched to the outer-side column through a space between the two connection pads 12 (1N and 3P) provided on the inner-side column and is connected to a connection pad 12 (2N) provided on the outer-side column in a state of being extended horizontally in the row direction side by side with the connection pad 12 (3P) close to the N-channel signal line 11N.

In the same way as the second row, the P-channel signal line 11P pertaining to the differential-line pair provided on the fourth row is stretched to the outer-side column through a space between two connection pads 12 (3N and 5P) provided on the inner-side column and is connected to a connection pad 12 provided on the outer-side column in a state of being extended horizontally in the row direction side by side with the connection pad 12 (3N) close to the P-channel signal line 11P whereas the N-channel signal line 11N pertaining to the differential-line pair provided on the fourth row is stretched to the outer-side column through a space between the two connection pads 12 (3N and 5P) provided on the inner-side column and is connected to a connection pad 12 provided on the outer-side column in a state of being extended horizontally in the row direction side by side with the connection pad 12 (5P) close to the N-channel signal line 11N.

### Characteristics of the Conductive-Layer Pattern of the Wiring Board

Prominent characteristics of the conductive-layer pattern of the flexible wiring board 1 are described as follows. As is obvious from the configuration described above, the connection pads 12 in this embodiment are laid out to form two columns, that is, the inner-side column and the outer-side column. Two connection pads 12 connected to lines pertaining to the same differential-line pair for transmitting differential signals are provided at locations adjacent to each other on the same column which is either the inner-side column or the outer-side column. In addition, a connection pad 12 provided on the inner-side column is shifted away in the horizontal direction from a connection pad 12 provided on the outer-side column only by a distance equal to the width of the connection pad 12.

On top of that, the conductive-layer pattern of the flexible wiring board 1 is also characterized in that a differential-line pair 11 connected to two connection pads 12 provided at locations adjacent to each other on the outer-side column is stretched through an area between two connection pads 12 provided at locations adjacent to each other on the inner-side column.

### Structure of the Other Edge of the Wiring Board

The above description explains the structure on a specific one of the two sides separated away from each other in the line direction in the flexible wiring board 1. However, the configuration on the other one of the two sides can be made identical with the configuration on the specific one of the two sides.

In order to make the lengths of lines pertaining to differential-line pairs 11 provided on even-numbered and odd-numbered rows uniform, however, it is desirable to connect a differential-line pair 11, which is provided on an odd-numbered row and connected to two connection pads 12 provided on the inner-side column on the edge shown in FIGS. 1A to 1C as the edge on the specific one of the two sides separated away from each other in the line direction in the flexible wiring board 1, to two adjacent connection pads 12 provided on the outer-side column on the edge on the other side not shown in the figure. By the same token, a differential-line pair 11, which is provided on an even-numbered row and connected to two connection pads 12 provided on the outer-side column on the edge shown in FIGS. 1A to 1C as the edge on the specific one of the two sides separated away from each other in the line direction in the flexible wiring board 1, is connected to two adjacent connection pads 12 provided on the inner-side column on the edge on the other side not shown in the figure.

### Connector Structure

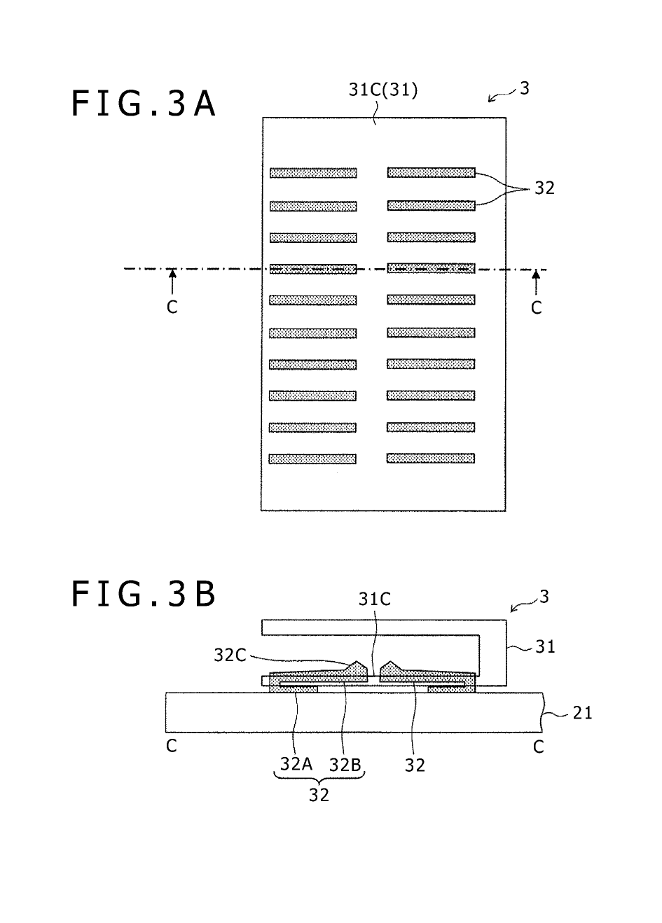

FIG. 3B is a diagram roughly showing a cross section of a typical configuration of a connector 3 according to the embodiments of the present technology disclosed in this specification. On the other hand, FIG. 3A is a diagram showing a top view of a layout of connector terminals at the bottom of a socket 31 employed in the connector 3. FIG. 3B roughly shows a cross section along a C-C line shown in FIG. 3A. The connector 3 shown in FIG. 3B is the connector 3A shown in FIG. 2.

The connector 3 shown in FIG. 3B is a connection component mounted on the board 21 employed in the second wiring board 2A shown in FIG. 2. In general, the board 21 is a laminated wiring board created as a stack of a plurality of wiring layers, any two of which are separated away from each other by an insulation layer.

The connector 3 is provided with a connector socket 31 having a side surface thereof serving as an insertion opening through which the flexible wiring board 1 is inserted into the inside of the connector 3. The connector socket 31 is the connector socket 31A shown in FIG. 2. A space on the inner side of the insertion opening on the side surface of the connector 3 functions as a socket acceptor-section.

On the bottom plate 31C of the connector socket 31, a plurality of terminal bodies 32 of the connector socket 31 are provided. As many terminal bodies 32 as the connection pads 12 laid out to form a connection-pad array having the two columns (that is, the inner-side column and the outer-side column) as shown in FIG. 1A are laid out to form a terminal-body array having two columns corresponding to the inner-side column and the outer-side column respectively as shown in FIG. 3A. Thus, when the flexible wiring board 1 is inserted into the connector 3, the connection pads 12 employed in the flexible wiring board 1 are brought into contact with the terminal bodies 32 of the connector 3 on a 1-to-1 basis.

The terminal body 32 is configured to have an external terminal portion 32A provided on the rear surface of the bottom plate 31C of the connector socket 31 and a connection portion 32B folded back from the external terminal portion 32A. The connection portion 32B has a contact protrusion 32C protruding from the upper surface of the vicinity of the edge of connection portion 32B to the space inside the connector acceptor-section.

As described above, the terminal bodies 32 are laid out to form a terminal-body array having two columns in such a way that each of the terminal bodies 32 on a specific one of the columns is provided at a position adjacent in the row direction to the corresponding one of the terminal bodies 32 on the other one of the columns. The two terminal bodies 32 adjacent to each other are oriented so that the contact protrusions 32C of the terminal bodies 32 are close to each other.

The terminal body 32 can be fixed on the bottom plate 31C of the connector socket 31 because the external terminal portion 32A and the connection portion 32B which are employed in the terminal body 32 hold a portion of the bottom plate 31C.

The terminal body 32 is made of a conductive material having a low specific resistance. Due to the elastic force of the material and the folded-back structure of the material, the terminal body 32 also functions as a plate spring for applying a force to the flexible wiring board 1 as follows. When the flexible wiring board 1 is inserted into the space inside the connector 3, the terminal body 32 is elastically deformed, pushing down the contact protrusion 32C so that a force is applied to the flexible wiring board 1.

The connector 3 having the configuration described above is electrically connected to a conductive layer provided on the upper surface of the board 21. The upper surface is also referred to as a mounting surface. The conductive layer itself is not shown in FIGS. 3A and 3B. The connector 3 can be electrically connected to the conductive layer by adoption of the soldering technique or by making use of another connection member.

The conductive layer created on the mounting surface of the board 21 but not shown in the figure is an independent land connected to a wiring layer provided on the mounting surface of the board 21 or the upper surface of via holes created in the board 21. The via holes themselves are also not shown in FIGS. 3A and 3B.

As described above, the terminal bodies 32 are laid out to form two columns which are a column relatively close to the side for insertion of the flexible wiring board 1 and a column relatively far away from the side. In FIG. 3B, the side for insertion of the flexible wiring board 1 is the left-hand side. Each terminal body 32 provided on the column relatively close to the side for insertion of the flexible wiring board 1 is connected to a wiring layer provided inside the board 21 or on the rear surface of the board 21. This wiring layer is also not shown in FIGS. 3A and 3B. Such a terminal body 32 is connected to the wiring section typically through a land and a via hole. Thus, the terminal body 32 is connected to an electronic circuit through the wiring layer.

On the other hand, each terminal body 32 provided on the column relatively far away from the side for insertion of the flexible wiring board 1 is connected to the electronic circuit through the wiring layer provided on the mounting surface of the board 21. The column relatively far away from the side for insertion of the flexible wiring board 1 is also referred to as an inner-side column which is the right-hand side in FIG. 3B.

Connections between the Wiring Board and the Connector

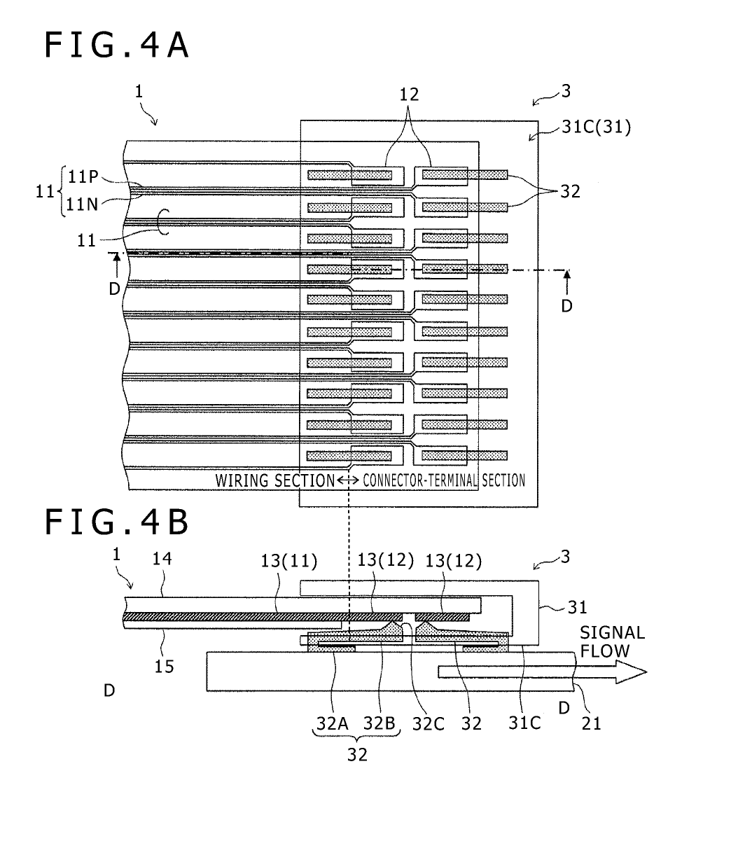

FIGS. 4A and 4B are diagrams showing a state in which signals can be transmitted in the electronic apparatus shown in FIG. 2 through the connector 3 shown in FIGS. 3A and 3B and the flexible wiring board 1 shown in FIGS. 1A to 1C after the flexible wiring board 1 has been inserted into the connector 3 in order to electrically connect the flexible wiring board 1 to the connector 3. To be more specific, FIG. 4A is a top-view diagram (or a perspective diagram) showing superposition of conductive-layer patterns in the electronic apparatus. More particularly, FIG. 4A shows a state in which connection pads employed in the flexible wiring board 1 and terminal bodies employed in the connector 3 have been brought into contact with each other in the electronic apparatus. On the other hand, FIG. 4B is a cross-sectional diagram roughly showing the electronic apparatus seen along a D-D line shown in FIG. 4A.

As shown in FIGS. 4A and 4B, with the flexible wiring board 1 already inserted into the connector 3, the connection pads 12 employed in the flexible wiring board 1 and the terminal bodies 32 employed in the connector 3 are put in a state of being brought into contact with each other on a 1-to-1 basis.

As explained earlier by referring to FIGS. 1A to 1C, any two connection pads 12 connected to the same differential-line pair 11 are provided at locations adjacent to each other on the same column and a differential-line pair 11 connected to two connection pads 12 provided on the outer-side column is stretched through an area between two connection pads 12 provided on the inner-side column.

For the sake of compatibility with the configuration described above, every two terminal bodies 32 serving as connection portions for transmitting differential signals in the connector 3 are provided at locations adjacent to each other on the same column. Thus, in the state shown in FIGS. 4A and 4B, the two terminal bodies 32 connected to the two connection pads 12 pertaining to the same differential-line pair for transmitting the differential lines are electrically connected to a terminal pair for inputting and outputting the differential signals of the electronic circuit.

It is to be noted that, when the flexible wiring board 1 is inserted into the connector 3, the contact protrusion 32C of the terminal body 32 employed in the connector 3 rubs against the corresponding connection pad 12 employed in the flexible wiring board 1 and slides over the connection pad 12. It is thus desirable to provide the connection pad 12 with a long rectangular shape oriented in the board insertion direction or the line direction. In addition, since a thin differential-line pair unprotected by a insulation layer 15 exists in an area between connection pads 12 provided on the inner-side column, in order to prevent the differential lines of the differential-line pair from being injured, it is desirable to provide the terminal body 32 with a long shape thinner than the width of the connection pad 12.

### 2: Second Embodiment

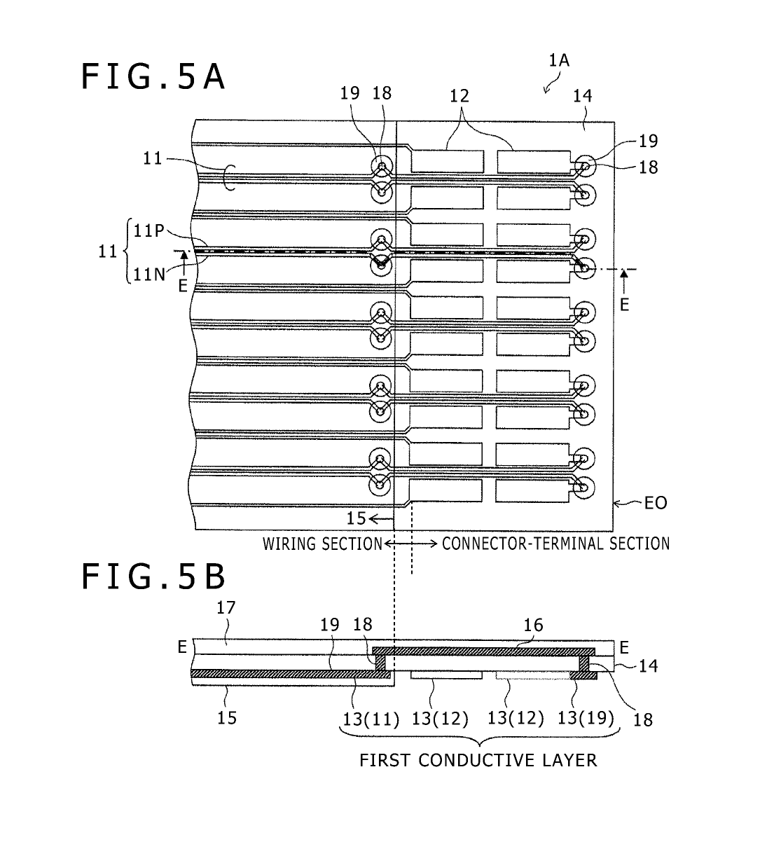

FIG. 5A is a top-view diagram (or a perspective diagram) showing a conductive-layer pattern of a flexible wiring board 1A according to a second embodiment whereas FIG. 5B is a diagram showing a cross section along an E-E line shown in FIG. 5A.

As shown in FIG. 5B, the flexible wiring board 1A is a flexible wiring board having a two-layer structure including two conductive layers 13 and 16 created on both the surfaces of an insulation layer 14 serving as a core. The insulation layer 14 is the board provided by the embodiments of the present technology disclosed in this specification. Seen in this light, the flexible wiring board 1A having such a structure is also referred to as a flexible wiring board of the both-surface type.

FIG. 5B shows a state in which the flexible wiring board 1A is inserted into a connector acceptor-section which is a space inside the socket of the connector. In this state, an A surface which is the lower-side surface of the flexible wiring board 1A and a conductive layer on the A surface are referred to as a first conductive layer 13 whereas a B surface which is the upper-side surface of the flexible wiring board 1A and a conductive layer on the B surface are referred to as a second conductive layer 16.

As described above, the flexible wiring board 1A shown in FIG. 5B has two layers (that is, the conductive layers 13 and 16) on respectively the two surfaces of the insulation layer 14. In the following description, the conductive layer 16 is referred to as a second conductive layer 16 as opposed to the conductive layer 13 which can be regarded as a first conductive layer. The first conductive layer 13 created on the lower-side surface (or the A surface) is patterned to form differential-line pairs 11 in the wiring section and connection pads 12 in the connector-terminal section. Such a configuration itself is identical with that of the first embodiment.

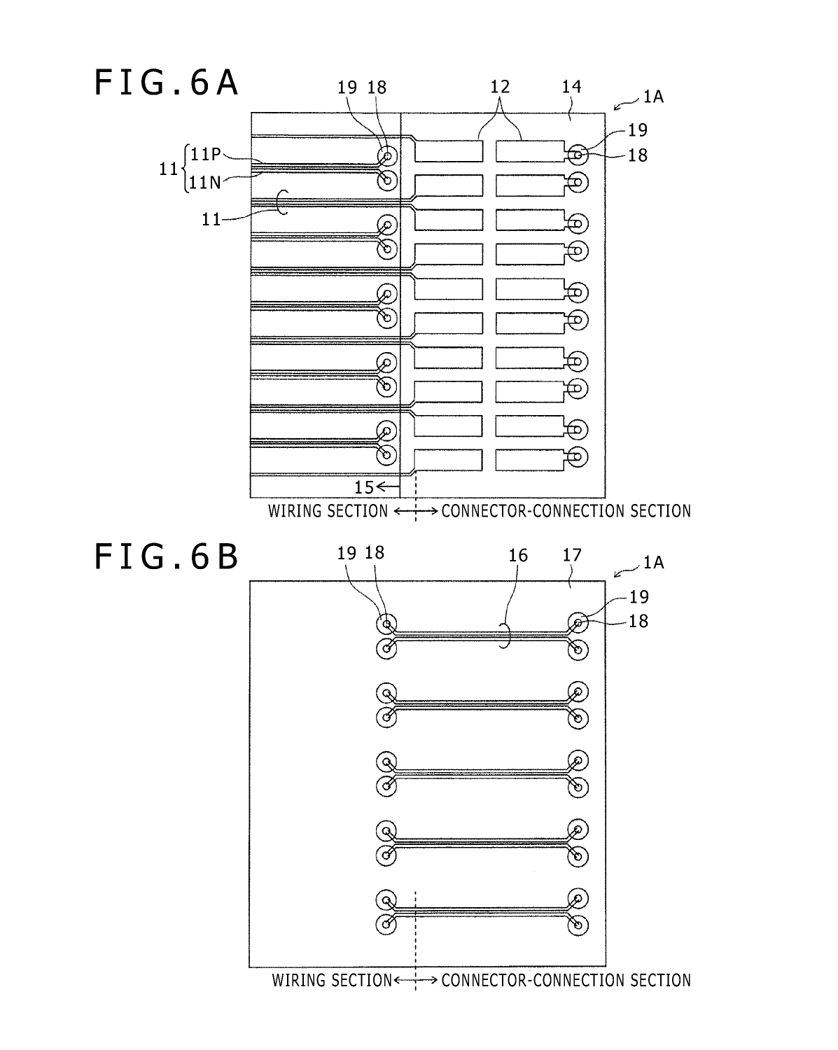

FIG. 6A is a diagram showing A-surface lines on the conductive layer 13 whereas FIG. 6B is a diagram showing B-surface lines on the second conductive layer 16.

In the case of the first embodiment, about one-half of differential-line pairs 11 are stretched from the wiring section through areas each existing between any two adjacent connection pads 12 provided in the connector-terminal section and are connected to connection pads 12 provided on the outer-side column of the connector-terminal section. Such a differential-line pair 11 is referred to as a differential-line pair 11 stretched along an even-numbered row.

In the case of the second embodiment, on the other hand, about one-half of differential-line pairs 11 are also stretched from the wiring section but connected to a specific one of the edges of the second conductive layer 16 on the side of the upper-side surface (or the B surface) of the insulation layer 14 through via holes 18. Typically, the differential-line pairs 11 provided on even-numbered rows are taken as such differential-line pairs 11. The other one of the edges of the second conductive layer 16 is electrically connected to connection pads 12 on the outer-side column on the side of the edge side E0 of the flexible wiring board 1A through other via holes 18.

In FIGS. 5A, 6A and 6B, circles 19 each enclosing a via hole 18 are shown. The circle 19 is the landing portion of the via hole 18. The landing portion is referred to as a land created on the conductive layer 13. If the via hole 18 can be connected to a link portion extended to the conductive layer 13 on the outer-side column without a positional shift, the circle 19 is not required. In this embodiment, a circle 19 is provided on a portion connecting a differential-line pair 11 to the specific one of the edges of the second conductive layer 16 at the wiring section. In addition, a circle 19 is also provided on a portion connecting a connection pad 12 on the outer-side column to the other one of the edges of the second conductive layer 16 at the connector-terminal section.

As already explained earlier by referring to FIGS. 4A and 4B in the description of the first embodiment, when the flexible wiring board 1A having the configuration described above is inserted into the connector 3, on the side of the lower-side surface (or the A surface), the connection pads 12 provided on the two columns are connected to the terminal bodies 32 on the two columns on a 1-to-1 basis.

In the case of the second embodiment, at that time, the thin differential-line pair 11 in the connector-terminal section has been created on the second conductive layer 16. Thus, when the flexible wiring board 1A is inserted into the connector 3, the contact protrusion 32C of the terminal body 32 employed in the connector 3 is not exposed to the corresponding connection pad 12 employed in the flexible wiring board 1A. It is to be noted that, in the case of the first embodiment, the contact protrusion 32C of the terminal body 32 employed in the connector 3 rubs against the corresponding connection pad 12 employed in the flexible wiring board 1 and slides over the connection pad 12 when the flexible wiring board 1 is inserted into the connector 3. For this reason, the flexible wiring board 1A of the both-surface type has a merit that the thin differential-line pair 11 is not injured when the flexible wiring board 1A is inserted into the connector 3.

In the top-view diagram (or the perspective diagram) of FIG. 5A, a thin differential-line pair 11 created on the second conductive layer 16 is shown as a pair placed at a location between connection pads 12. Since the differential-line pair 11 in the connector-terminal section has been created from the second conductive layer 16, however, without bringing the differential-line pair 11 into contact with a connection pad 12 composed of the conductive layer 13, both can be superposed on each other as a transparent planar pattern.

In general, if the differential-line pair 11 also transmits noises having the same phase and the same amplitude for both the two lines, the noises can be eliminated completely by carrying out signal processing. For this reason, the two lines are stretched along locations very close to each other as shown in FIG. 5A. As shown in the figure, the differential-line pair 11 in the connector-terminal section is accommodated in an area between connection pads 12.

It is to be noted that, if the distance between the two lines pertaining to the same differential-line pair 11 in the connector-terminal section is increased to such a value that the two lines overlap the connection pads 12 a little bit, it is desirable to also increase the distance between the two lines pertaining to the same differential-line pair 11 in the wiring section by about the same distance increase. However, it is necessary to set the distance between differential-line pairs 11 at a value sufficiently longer than the distance between the two lines pertaining to the same differential-line pair 11. Thus, it is nice to increase the distance between the two lines pertaining to the same differential-line pair 11 in the connector-terminal section to such a value that the distance between differential-line pairs 11 is still sufficiently longer than the distance between the two lines pertaining to the same differential-line pair 11.

In addition, the distance between the two lines pertaining to the same differential-line pair 11 is increased because of necessity from, among others, fine manufacturing described as follows.

It is desirable to increase the width of the line to a certain degree for the purpose of raising the yield and the manufacturing precision. In some cases, however, the area in which a number of differential-line pairs 11 and the group of connection pads 12 are provided is limited. In such cases, in place of the first embodiment of the one-surface type, the flexible wiring board 1A having the two-surface type in accordance with the second embodiment is used in order to implement a wiring board meeting such necessities.

### 3: Third Embodiment

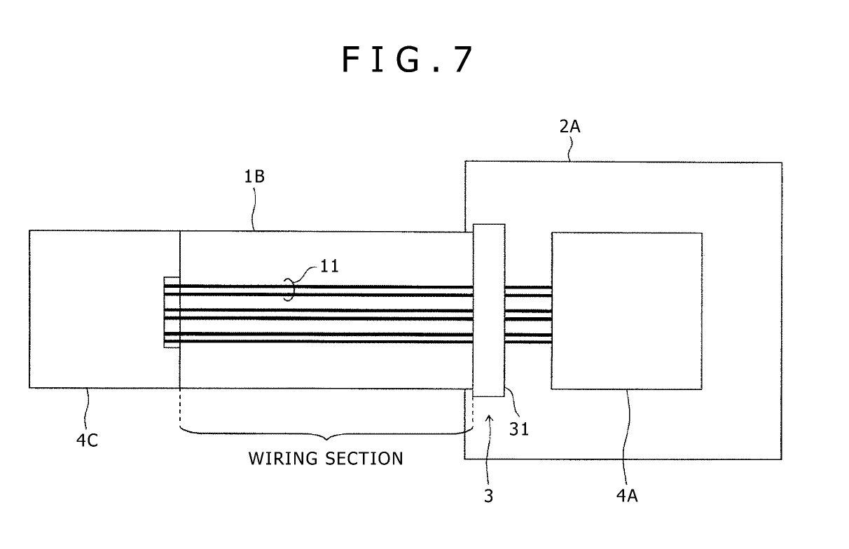

FIG. 7 is a diagram showing the configuration of a flexible wiring board 1B according to a third embodiment and the configuration of an electronic apparatus employing the flexible wiring board 1B.

On a specific one of the edges of the flexible wiring board 1B shown in FIG. 7, a connector-terminal section like the one used in the first or second embodiment is provided. The specific one of the edges of the flexible wiring board 1B is the edge on the right-hand side of FIG. 7. The connector-terminal section used in the first embodiment is shown in FIGS. 1A to 1C whereas the connector-terminal section used in the second embodiment is shown in FIGS. 5A and 5B. Thus, the specific one of the edges of the flexible wiring board 1B shown in FIG. 7 as a first wiring board is inserted into the connector 3 in order to connect the flexible wiring board 1B to a second wiring board 2A. On the second wiring board 2A, a semiconductor integrated circuit 4A is mounted in the same way as the configuration shown in FIG. 2. Accordingly, the semiconductor integrated circuit 4A is capable of inputting and outputting differential signals through the flexible wiring board 1B.

The other one of the edges of the flexible wiring board 1B can be connected directly to a semiconductor integrated circuit 4C, which serves as another electronic circuit, without making use of a connector. FIG. 7 is a diagram showing a state in which the semiconductor integrated circuit 4C is directly connected to the other one of the edges of the flexible wiring board 1B.

On the wiring section of the flexible wiring board 1B, a plurality of differential-line pairs 11 are provided in the same way as the first and second embodiments. However, the other end of each of the differential-line pairs 11 is connected to connection pads of the semiconductor integrated circuit 4C without making use of a connector. The other end of each of the differential-line pairs 11 is the end on the left-hand side in FIG. 7. In general, the semiconductor integrated circuit 4C is connected to the differential-line pairs 11 by adopting one of a variety of techniques. For example, the semiconductor integrated circuit 4C is connected to the differential-line pairs 11 by adoption of the solder bumping technique or by making use of an anisotropic conductive adhesive film.

### 4: Fourth Embodiment

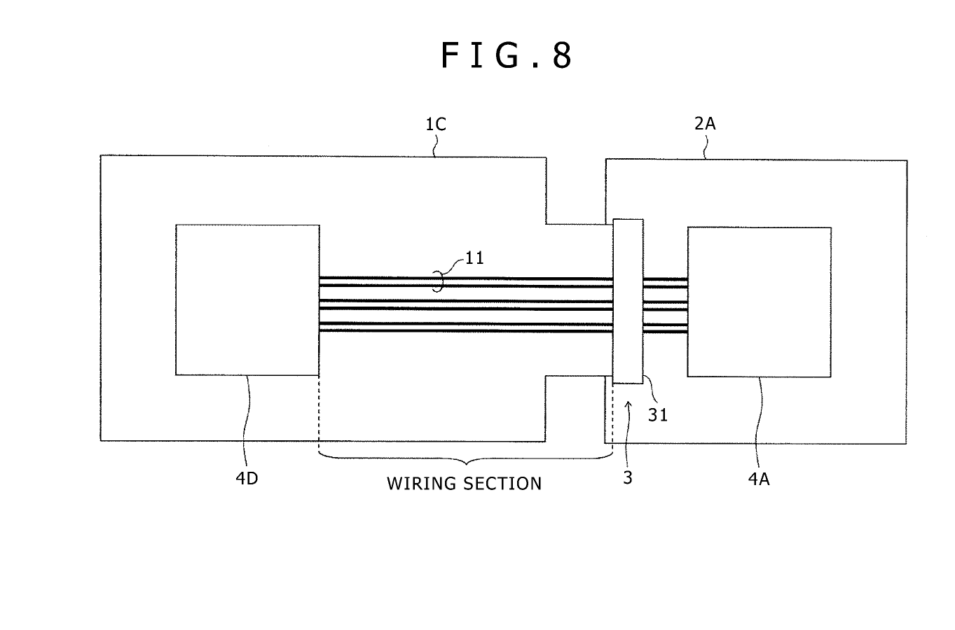

FIG. 8 is a diagram showing the configuration of a wiring board 1C according to a fourth embodiment and the configuration of an electronic apparatus employing the wiring board 1C. A typical example of the wiring board 1C shown in FIG. 8 is a printed wiring board.

The printed wiring board makes use of a board serving as a relatively rigid insulation layer in place of the insulation layer made of flexible resin to serve as the board of the flexible wiring board according to the first embodiment and other flexible wiring boards. A typical representative of such a relatively rigid insulation layer is a glass epoxy resin layer. Thus, unlike the flexible wiring board, the printed wiring board is not flexible. However, the connection pads according to the embodiments of the present technology disclosed in this specification can be positioned in the same way and, in addition, the same configuration of the connector can be implemented.

To put it concretely, the wiring board 1C shown in FIG. 8 has a connector-terminal section provided on a specific one of the edges of the wiring board 1C to serve as a connector-terminal section like the one used in the first or second embodiment. The specific one of the edges of the flexible wiring board 1B is the edge on the right-hand side of FIG. 8. The connector-terminal section used in the first embodiment is shown in FIGS. 1A to 1C whereas the connector-terminal section used in the second embodiment is shown in FIGS. 5A and 5B. Thus, the specific one of the edges of the wiring board 1C shown in FIG. 8 as a first wiring board is inserted into the connector 3 in order to connect the wiring board 1C to a second wiring board 2A. On the second wiring board 2A, a semiconductor integrated circuit 4A is mounted in the same way as the configuration shown in FIG. 2. Accordingly, the semiconductor integrated circuit 4A is capable of inputting and outputting differential signals through the wiring board 1C.

The other one of the edges of the wiring board 1C can be connected directly to a semiconductor integrated circuit 4D, which serves as another electronic circuit, without making use of a connector. FIG. 8 is a diagram showing a state in which the semiconductor integrated circuit 4D is directly connected to the other one of the edges of the wiring board 1C.

On the wiring section of the wiring board 1C, a plurality of differential-line pairs 11 are provided in the same way as the first and second embodiments. On the other end side of the differential-line pairs 11, however, there is a mounting area in which the semiconductor integrated circuit 4D serving as another electronic circuit is provided. In FIG. 8, the other end side of the differential-line pairs 11 is the left-hand side. FIG. 8 is a diagram showing a state in which the semiconductor integrated circuit 4D is has been mounted in the mounting area.

In general, the semiconductor integrated circuit 4C is connected to the differential-line pairs 11 by adopting one of a variety of techniques. For example, the semiconductor integrated circuit 4C is connected to the differential-line pairs 11 by adoption of the solder bumping technique or by making use of an anisotropic conductive adhesive film. Thus, the wiring board 1C is provided with an internal connection pad group in advance. The internal connection pad group not shown in the figure is used for connecting the semiconductor integrated circuit 4C to the differential-line pairs 11.

### 5: Typical Modified Versions

### First Typical Modified Versions

The first to third embodiments each implementing a flexible wiring board and the fourth embodiment implementing a printed wiring board have been taken as examples to explain the wiring board according to the embodiments of the present technology disclosed in this specification.

However, the wiring board according to the embodiments of the present technology disclosed in this specification is by no means limited to the flexible wiring board and the printed wiring board.

In the wiring board according to the first to third embodiments of the present technology disclosed in this specification for example, it is possible to make use of a board made of glass epoxy resin having good rigidity to serve as a base layer as is the case with the printed wiring board according to the fourth embodiment. In addition, in the fourth embodiment, a flexible wiring board or the like can be used as the printed wiring board according to the embodiments of the present technology disclosed in this specification.

On top of that, the second wiring boards shown in FIGS. 2, 7 and 8 do not have to be printed wiring boards. In addition, the connector connected to the wiring board according to the embodiments of the present technology disclosed in this specification is by no means limited to a connector provided on another wiring board. For example, it is possible to insert the flexible wiring board according to the embodiments of the present technology disclosed in this specification or the printed wiring board according to the embodiments of the present technology disclosed in this specification into the socket of a connector provided on a case constructed inside an electronic apparatus or provided on a partition wall constructed inside an electronic apparatus.

### Second Typical Modified Versions

In the second embodiment, a plurality differential-line pairs 11 are all created on a conductive layer 13. As an example, however, it is possible to provide a typical configuration in which only the differential-line pairs 11 for the odd-numbered rows are created on a conductive layer 13 whereas only the differential-line pairs 11 for the even-numbered rows are created on a second conductive layer 16.

In addition, it is possible to provide a typical configuration including a plurality of conductive layers such as first, second and third conductive layers even though the demand for such a configuration is not so strong. In the case of such a configuration, at locations where a plurality of connection pads 12 on the first conductive layer are connected to differential-line pairs 11, the second and third conductive layers are used. Nevertheless, such a configuration is not excluded from the present technology disclosed in this specification. On top of that, the present technology disclosed in this specification also does not exclude a configuration in which a plurality of differential-line pairs 11 are created from three or more conductive layers.

It is to be noted that the present technology disclosed in this specification has characteristic structures of lines for transmitting differential signals and characteristic structures of connections of the lines. Thus, even though it is not worth mentioning in particular, there are some cases in which the wiring board includes lines for transmitting non-differential and low-speed signals and/or non-differential and low-speed voltages. In such cases, for example, connection pads having the same pitch are added to the column end sides separated away from each other in the column direction. The connection pads are added to the column end sides of each of the two columns provided for differential signals as shown in FIGS. 1A to 1C. It is nice to allocate the group of the connection pads added to the left-hand and right-hand sides with respect to the line direction to lines for transmitting low-speed signals and/or low-speed voltages.

The wiring boards according to the first to fourth embodiments as well as the first and second typical modified versions have a variety of merits described as follows.

For the two lines included in each differential-line pair in the wiring board as two lines for the P and N channels, at any location along the longitudinal direction, the physical shape can be made completely symmetrical with respect to the direction in which the two lines are separated from each other. This symmetry allows generation of a wiring skew in the wiring board to be eliminated. By elimination of the wiring skew, it is possible to prevent the quality of the waveform of a transmitted signal from deteriorating. In addition, it is possible to suppress undesired radiations caused by EMI (Electromagnetic Interferences).

The two lines included in a differential-line pair in the wiring board as two lines for the P and N channels are both connected to connection pads provided on the inner-side column or both connected to connection pads provided on the outer-side column.

Thus, in all signal transmission conductors each including a line and a connection pad, the symmetry described above is assured. Accordingly, a differential skew is not generated not only in the wiring section, but also in the connector-terminal section.

The following description explains the differential skew in the connector-terminal section by comparing a case described in Patent Document 1 with a case in which the present technology disclosed in this specification is applied. In the following description, FIG. 4B is properly referred to.

In the structure described in Patent Document 1, the connection pad connected to a specific one of the two lines for transmitting the differential signals is provided on the outer-side column whereas the connection pad connected to the other one of the two lines for transmitting the differential signals is provided on the inner-side column. Thus, in this case, the differential signal transmitted by the specific line propagates to a printed wiring board serving as a second wiring board in a direction indicated by a phrase of ‘signal flow’ shown in FIGS. 4A and 4B by way of the connection pad provided on the outer-side column. On the other hand, the differential signal transmitted by the other line propagates to another wiring layer of the printed wiring board by way of the connection pad provided on the inner-side column. In order for the differential signal transmitted by the other line to pass through the connection pad provided on the inner-side column, the signal must typically propagate by way of a via hole not shown in the figure to the other wiring layer provided inside the board or provided on the rear surface of the board. As an alternative, the differential signal transmitted by the other line must be once detoured in a direction opposite to the direction indicated by the phrase of ‘signal flow.’ Thus, due to a difference in signal propagation structure between the two differential signals, a differential skew is always generated between the two differential signals.

If the present technology disclosed in this specification is applied, on the other hand, there is no difference in signal propagation structure between the two differential signals. Thus, the differential skew caused by the difference in signal propagation structure between the two differential signals is not generated. Even if such a differential skew is generated, the size of the skew is substantially reduced.

The connector connection structure in which a portion of the wiring board is inserted into the connector as described above has a low cost due to the simplicity of the structure and low prices of components used in the structure. Even though there are a large number of various applications of the present technology disclosed in this specification, the number of such components never increases or the structure never becomes complicated. Thus, by applying the present technology disclosed in this specification, it is possible to implement a connector connection structure offering advantages such as reduction of the cost and avoidance of a differential skew or considerable reduction of the size of the skew.

In addition, since the present technology disclosed in this specification provides symmetry at both the edges of the wiring board, the present technology disclosed in this specification can be applied to a wide range of wiring boards including not only those according to the first and second embodiments, but also those according to the third and fourth embodiments.

The present disclosure contains subject matter related to that disclosed in Japanese Priority Patent Application JP 2011-220178 filed in the Japan Patent Office on Oct. 4, 2011, the entire content of which is hereby incorporated by reference.

It should be understood by those skilled in the art that various modifications, combinations, sub-combinations and alterations may occur depending on design requirements and other factors in so far as they are within the scope of the appended claims or the equivalents thereof.

What is claimed is:

1. A wiring board comprising:
a differential-line pair including two lines for transmitting differential signals; and
two connection pads each electrically connected to one of said two lines pertaining to one of said differential-line pairs, wherein
a plurality of said differential-line pairs are laid out side by side,
a plurality of said connection pads are provided to form a plurality of columns, and
on each of said columns of said connection pads, any two said connection pads electrically connected to said lines pertaining to the same differential-line pair are provided at locations adjacent to each other on the same one of said columns.

2. The wiring board according to claim 1, wherein said connection pads are each a terminal of an insertion-type connector.

3. The wiring board according to claim 2, wherein:
said connection pads are provided in basic configuration units each including two of said connection pads; and
a portion of said wiring board is to be inserted as an inserted edge into a connector acceptor-section of a connector employed in another board.

4. The wiring board according to claim 3, wherein:
said connection pads are provided to form two columns;
two said connection pads connected to each of said differential-line pairs are provided on the same one of said two columns; and
two said connection pads provided on a specific one of said two columns are separated away from two said connection pads provided on the other one of said two columns by an inter-column distance equal to the size of each of said connection pads.

5. The wiring board according to claim 1, wherein, at a specific one of the two line-direction ends of any one of said differential-line pairs each including two aforementioned lines, two said connection pads connected to said two aforementioned lines respectively are created line-symmetrically with respect to a symmetry axis passing through the center of a distance separating said two aforementioned lines away from each other.

6. The wiring board according to claim 1, wherein:
at each of the two line-direction ends of each of said differential-line pairs, two aforementioned connection pads are provided to serve as connector terminals to be inserted into a connector acceptor-section of a connector employed in a board other than said wiring board; and
all said connection pads form a plurality of columns each taking said two aforementioned connection pads as a basic configuration unit.

7. The wiring board according to claim 1, wherein:
at a specific line-direction end of each of said differential-line pairs, two aforementioned connection pads are provided to serve as connector terminals to be inserted into a connector acceptor-section of a connector employed in a board other than said wiring board so that all said connection pads form a plurality of columns each taking said two aforementioned connection pads as a basic configuration unit; and
at the other line-direction end of each of said differential-line pairs, an internal connection pad group to be connected to an electronic circuit mounted on said wiring board is provided.

8. The wiring board according to claim 1, said wiring board further having:
a base board; and
a conductive layer supported by said base board to serve as a conductive layer on which said differential-line pairs and said connection pads are created.

9. The wiring board according to claim 8, wherein:
a plurality of said connection pads are provided on an outer-side column relatively close to an edge of said base board whereas a plurality of remaining ones of said connection pads are provided on an inner-side column relatively far away from the said of said base board;
said differential-line pairs laid out side by side to form a plurality of rows include first differential-line pairs provided for every other row and each of said lines pertaining to said first differential-line pairs is connected to one of said connection pads provided on said inner-side column; and
said differential-line pairs laid out side by side to form said rows include second differential-line pairs provided alternately with said first differential-line pairs and each of said lines pertaining to said second differential-line pairs is extended to one of said connection pads provided on said outer-side column through an area between said connection pads provided on said inner-side column.

10. The wiring board according to claim 1, said wiring board further having:
a base board;
an insulation layer; and
two conductive layers supported by said base board to sandwich said insulation layer, wherein
on a specific one of said two conductive layers, a plurality of said connection pads are provided on an outer-side column relatively close to an edge of said base board whereas a plurality of remaining ones of said connection pads are provided on an inner-side column relatively far away from said edge of said base board,
said differential-line pairs laid out side by side to form a plurality of rows include first differential-line pairs provided for every other row and each of said lines pertaining to said first differential-line pairs is connected to one of said connection pads provided on said inner-side column, and
said differential-line pairs laid out side by side to form said rows include second differential-line pairs provided alternately with said first differential-line pairs, the other one of said two conductive layers is connected to said connection pads provided on said outer-side column through a conductive via hole and said lines pertaining to said second differential-line pairs are electrically connected to said other one of said two conductive layers.

11. The wiring board according to claim 10, wherein:
said first differential-line pairs and said second differential-line pairs provided alternately with said first differential-line pairs are created from said specific one of said two conductive layers; and
said other one of said two conductive layers is connected to the end of each of said lines pertaining to each of said second differential-line pairs created from said specific one of said two conductive layers through another conductive via hole.

12. A connector comprising:
a socket into which a portion of a board provided with a plurality of connection-pad pairs each having two connection pads electrically connected to respectively two lines for transmitting differential signals is inserted; and
a plurality of terminal bodies which are provided inside said socket and rub against said connection pads to slide over said connection pads on a 1-to-1 basis when said portion of said board is inserted into said socket, wherein
said terminal bodies are laid out to form two columns composing a terminal-body matrix corresponding to a connection-pad matrix composed of said connection pads, and
every two of said terminal bodies serve as connection portions for transmitting said differential signals and are provided at locations adjacent to each other on the same one of said two columns.

13. The connector according to claim 12, wherein:
said terminal bodies are provided to form a reticular pattern in the area of said two columns;
pairs each including two of said terminal bodies and each serving as connection portions for transmitting said differential signals are provided to form said two columns; and
each of said pairs provided on a specific one of said two columns is shifted away from one of said pairs provided on the other one of said two columns by an inter-column distance equal to the size of each of said terminal bodies.

14. An electronic apparatus comprising:
a first wiring board;
a second wiring board; and
a connector for connecting said first wiring board to said second wiring board, wherein
an electronic circuit is mounted on at least one of said first wiring board and said second wiring board,
said first wiring board includes
a plurality of differential-line pairs each having two lines for transmitting differential signals, and
a plurality of connection-pad pairs each having two connection pads electrically connected to respectively said two lines pertaining to one of said differential-line pairs, and
in said first wiring board,
said differential-line pairs are laid out side by side,
said connection pads composing said connection-pad pairs are laid out to form a plurality of columns, and
said connection pads pertaining to any one of said connection-pad pairs are provided at locations adjacent to each other on the same one of said columns.
